(19) United States
(12) Patent Application Publication
(10) Pub. No.: US 2015/0187616 A1
(43) Pub. Date: Jul. 2, 2015

(54) MECHANISMS OF ADJUSTABLE LASER BEAM FOR LASER SPIKE ANNEALING

(71) Applicant: Taiwan Semiconductor Manufacturing Co., Ltd., Hsin-Chu (TW)

(72) Inventors: Po-Chun HUANG, Hsinchu City (TW); Lee-Te TSENG, Hsinchu City (TW); Wen-Chieh HUANG, Tainan City (TW); Chi-Fu YU, Taipei City (TW); Ming-Te CHEN, Hsinchu City (TW)

(73) Assignee: Taiwan Semiconductor Manufacturing Co., Ltd., Hsin-Chu (TW)

(21) Appl. No.: 14/144,657

(22) Filed: Dec. 31, 2013

(51) Int. Cl. H01L 21/67; H01L 21/324; H01L 21/268

(52) U.S. Cl. CPC H01L 21/67115; H01L 21/268; H01L 21/324

(57) ABSTRACT

Mechanisms of adjustable laser beams for LSA (Laser Spike Annealing) are provided. A computing device receives input mask information relative to a silicon wafer, and analyzes the input mask information so as to generate a control signal. A laser generator generates a laser beam, and adjusts a beam length of the laser beam according to the control signal. Such mechanisms of the disclosure effectively eliminate the stitch effect on the silicon wafer and further increase the wafer yield.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of materials over a semiconductor substrate, and patterning the various material layers using lithography to form circuit components and elements thereon.

Semiconductor devices are increasingly scaled down and gate dielectrics become thinner. At such a small dimension, any tunneling through a gate dielectric layer to the underlying channel region significantly increases gate-to-channel leakage current and increases power consumption. Therefore, gate dielectrics are required to have a high density and fewer pores.

High-k materials are commonly used as gate dielectrics for MOSFET (Metal-Oxide-Semiconductor Field-Effect Transistor) devices. However, high-k materials have the disadvantage that their densities are lower than general thermally grown, low-k silicon dioxide. One of the methods of improving density is annealing, by which the material density is increased and therefore electrical properties are improved. However, there are many challenges related to the annealing process. Some general methods of gate-dielectric annealing are performed by RTA (Rapid Thermal Annealing), which requires temperatures as high as around 700° C. Since wafers are typically kept at a high temperature for a long period, general RTA has the drawbacks of agglomeration formation, high thermal budget cost, and high diffusion of impurities.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 shows a diagram of an LSA (Laser Spike Annealing) device in accordance with some embodiments of the disclosure;

FIG. 2 shows a diagram of an LSA device in accordance with some embodiments of the disclosure;

FIG. 3 shows a diagram of a laser generator in accordance with some embodiments of the disclosure;

FIG. 4 shows a diagram of a silicon wafer in accordance with some embodiments of the disclosure;

FIG. 5A shows a diagram of an LSA process without the adjustments of a laser beam;

FIG. 5B shows a diagram of an LSA process without the adjustments of a laser beam;

FIG. 5C shows a diagram of sheet resistances on a silicon wafer without adjustments of a laser beam;

FIG. 6A shows a diagram of an LSA process in accordance with some embodiments of the disclosure;

FIG. 6B shows a diagram of an LSA process in accordance with some embodiments of the disclosure;

FIG. 6C shows a diagram of sheet resistances on a silicon wafer in accordance with some embodiments of the disclosure; and

FIG. 7 shows a flowchart of a method for LSA in accordance with some embodiments of the disclosure.

### DETAILED DESCRIPTION

The making and using of the embodiments of the disclosure are discussed in detail below. It should be appreciated, however, that the embodiments can be embodied in a wide variety of specific contexts. The specific embodiments discussed are merely illustrative, and do not limit the scope of the disclosure.

It is to be understood that the following disclosure provides many different embodiments, or examples, for implementing different features of the disclosure. Specific examples of components and arrangements are described below to simplify the present disclosure. These are, of course, merely examples and are not intended to be limiting. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description that follows may include embodiments in which the first and second features are formed in direct contact, and may also include embodiments in which additional features may be formed between the first and second features, such that the first and second features may not be in direct contact. In addition, the like elements in various figures and embodiments are identified by the same or similar reference numerals.

Some variations of the embodiments are described. Throughout the various views and illustrative embodiments, like reference numbers are used to designate like elements. It is understood that additional steps can be provided before, during, and after the method, and some of the steps described can be replaced or eliminated for other embodiments of the method.

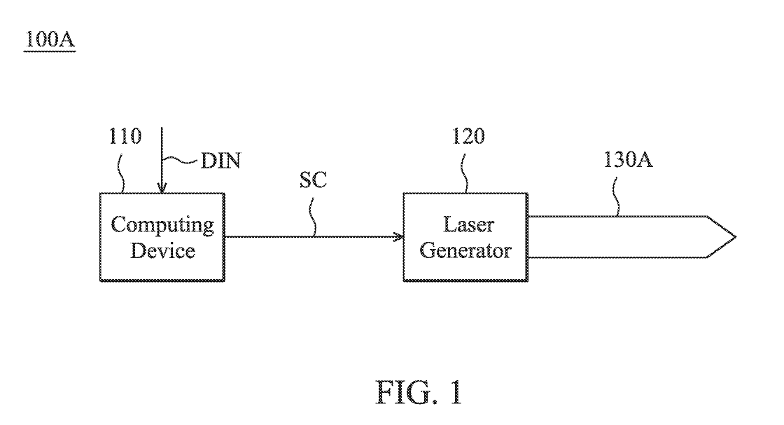

Embodiments of the disclosure provide mechanisms of adjustable laser beams for LSA (Laser Spike Annealing). The LSA has been developed to overcome the shortfalls of RTA (Rapid Thermal Annealing). FIG. 1 shows a diagram of an LSA device 100A in accordance with some embodiments of the disclosure. As shown in FIG. 1, the LSA device 100A at least includes a computing device 110 and a laser generator 120. The computing device 110 receives input mask information DIN. The input mask information DIN is related to the manufacture process of a silicon wafer which is divided into multiple dies. For example, the input mask information DIN may include a die size, a center die position, and/or a scrub-line dimension relative to the silicon wafer. The computing device 110 analyzes the input mask information DIN and accordingly generates a control signal SC. The laser generator 120 is coupled to the computing device 110. The laser generator 120 is configured to generate a laser beam 130A for LSA on the silicon wafer and adjust the beam length of the laser beam 130A according to the control signal SC. In some embodiments, the adjusted beam length of the laser beam 130A is substantially equal to the die size or a multiple of the die size. The relationship between the beam length and the die size will be illustrated in detail in the following figures and embodiments. The computing device 110 may include a custom-made or commercially available processor, a CPU (Central Processing Unit) or an auxiliary processor among several processors, a semiconductor based microprocessor (in the form of a microchip), a macroprocessor, one or more ASICs (Application Specific Integrated Circuits), suitably configured digital logic gates, and other electrical configurations including discrete elements both individually and in various combinations to coordinate the overall operation of the system. The structure of the laser generator 120 will be illustrated in detail in the following figures and embodiments.

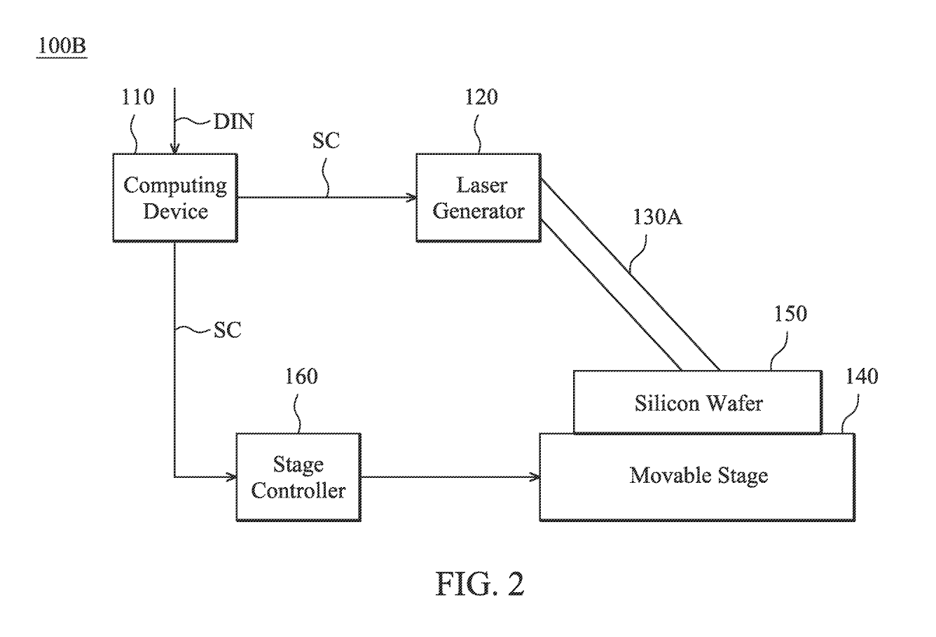

FIG. 2 shows a diagram of an LSA device 100B in accordance with some embodiments of the disclosure. As shown in FIG. 2, the LSA device 100B includes a computing device 110, a laser generator 120, a movable stage 140, a silicon wafer 150, and a stage controller 160. The computing device 110 receives input mask information DIN. The input mask information DIN is related to the manufacturing process of the silicon wafer 150. For example, the input mask information DIN may include a die size, a center die position, and/or a scrub-line dimension relative to the silicon wafer 150. The computing device 110 analyzes the input mask information DIN and accordingly generates a control signal SC. The laser generator 120 is configured to generate and adjust a laser beam 130A according to the control signal SC. In some embodiments, the adjusted beam length of the laser beam 130A is substantially equal to the die size or a multiple of the die size. The silicon wafer 150 may be made of a single crystal silicon material, an SOI (Silicon-on-Insulator) wafer, a wafer having a modified silicon layer, or a strained SOI wafer provided with an epitaxial layer. The silicon wafer 150 is positioned on and fixed to the movable stage 140. The stage controller 160 is configured to move the movable stage 140 and the silicon wafer 150 thereon according to the control signal SC from the computing device 110. In some embodiments, the control signal SC controls the movement of the laser beam 130A and the silicon wafer 150, or substrate, and the movable stage 140 remain stationary.

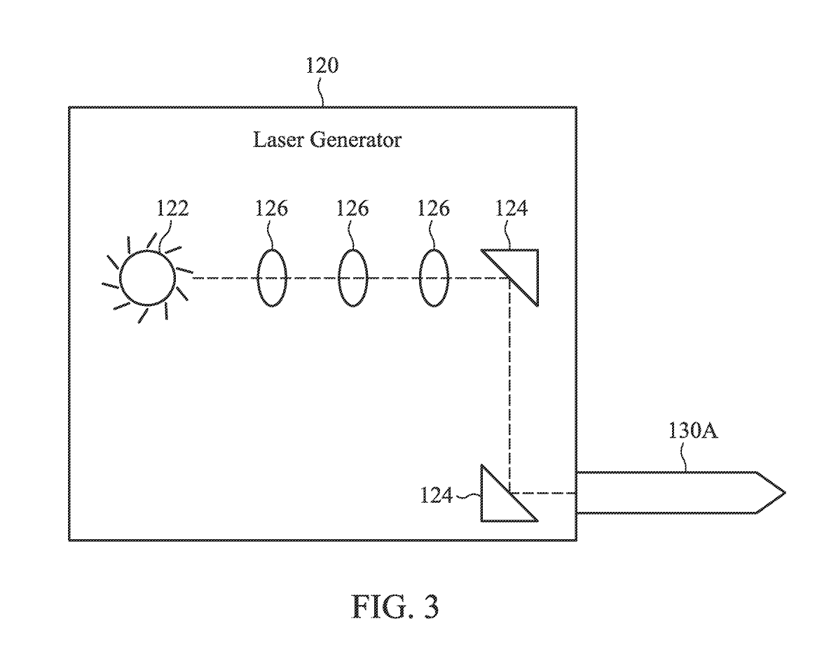

FIG. 3 shows a diagram of the laser generator 120 in accordance with some embodiments of the disclosure. As shown in FIG. 3, the laser generator 120 may include a laser source 122, one or more mirrors 124, and one or more prisms 126. For example, the laser source 122 may be a semiconductor laser source selected from quantum cascade laser sources and diode laser sources. In some embodiments, in the laser generator 120, a laser light is generated by the laser source 122. In some embodiments, the laser light is directed by the mirrors 124 and the prisms 126 to form the output laser beam 130A. In some embodiments, the mirrors 124 and the prisms 126 direct and adjust the generated laser light so as to control the waveform and the beam length of the laser beam 130A. It is understood that the number of mirrors 124 and prisms 126 and the light path thereof shown in FIG. 3 are just exemplary and not limitations of the embodiments. The aforementioned control signal SC may indicate some mirror and prism parameters so as to control the mirrors 124 and the prisms 126. For example, the mirror and prism parameters may include focal points, mirror and prism rotation angles, mirror and prism positions, and/or laser beam distortion relative to the mirrors 124 and the prisms 126. In such a manner, the waveform and the beam length of the laser beam 130A may be appropriately adjusted by the computing device 110 according to the analyzed input mask information DIN.

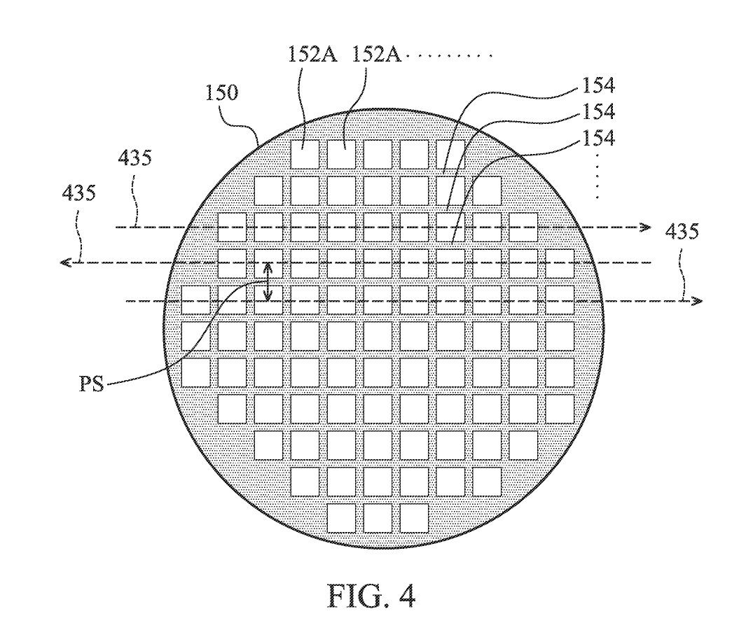

FIG. 4 shows a diagram of the silicon wafer 150 in accordance with some embodiments of the disclosure. As shown in FIG. 4, the silicon wafer 150 is divided into multiple dies 152A. The aforementioned die size may be defined as a length or a width of each die 152A. For example, each die 152A may have a length of 10 mm and a width of 7 mm, and the die size may be equal to 10 mm or 7 mm. In addition, multiple scrub-lines 154 are formed on the silicon wafer 150, and each scrub-line 154 is arranged between two adjacent dies 152A. During the LSA process, the laser beam 130A generated by the laser generator 120 is projected onto the silicon wafer 150, and the projected position of the laser beam 130A may be moved relative to the silicon wafer 150 along scanning paths 435 one after another. It is understood that the shape(s) of the scanning paths 435, or the scanning pattern, shown in FIG. 4 are just exemplary and not limitations of the embodiments. For example, the scanning paths 435 or the scanning pattern may include one or more parallel or perpendicular scan lines, in accordance with some embodiments. In some embodiments, the scanning paths 435 or the scanning pattern may include a variety of shapes, such as a W-shape, an M-shape, or an S-shape. In some embodiments, the stepping movement of the projected position of the laser beam 130A from one scanning path 435 to another is achieved by fixing the position of the laser beam 130A of the laser generator 120 and moving the movable stage 140 relative thereto. In alternative embodiments, the stepping movement of the projected position of the laser beam 130A from one scanning path 435 to another is achieved by fixing the movable stage 140 and moving the laser beam 130A of the laser generator 120 relative thereto. In some embodiments, each spacing PS between two adjacent scanning paths 435 is defined as a stepping size of the laser beam 130A or the movable stage 140.

The LSA process of the silicon wafer 150 may employ either a line scan or a step scan pattern. In some embodiments, in terms of the line scan pattern, the laser beam 130A scans across the silicon wafer 150 in one direction starting from the bottom of the silicon wafer 150, shift up in a longitudinal direction when the laser beam 130A reaches the end of the horizontal scan, scan across the silicon wafer 150 in the reverse horizontal direction, shift up in the longitudinal direction, and repeat the pattern until the entire surface of the silicon wafer 150 is scanned. The above scanning procedure is only an exemplary embodiment, rather than a limitation, of the disclosure, and different scan directions or patterns are also possible. For the step scan pattern, the laser beam 130A is in the form of a laser shot having a coverage area bound in both the longitudinal and the horizontal direction. In some embodiments, intermittent shots or pulses of laser beam are projected onto the wafer. In some embodiments, each shot or pulse of laser beam have a short duration, such as several milliseconds. In some embodiments, each shot or pulse of laser beam has the same or different duration. In some embodiments, a laser beam 130A is projected continuously onto a wafer during the LSA process. The laser shot may step scan in the horizontal direction across the silicon wafer 150 starting from the bottom of the silicon wafer 150, step up in the longitudinal direction, step scan across the silicon wafer 150 in the reverse horizontal direction, step up in the longitudinal direction, and repeat the pattern until the entire surface of the silicon wafer 150 is scanned.

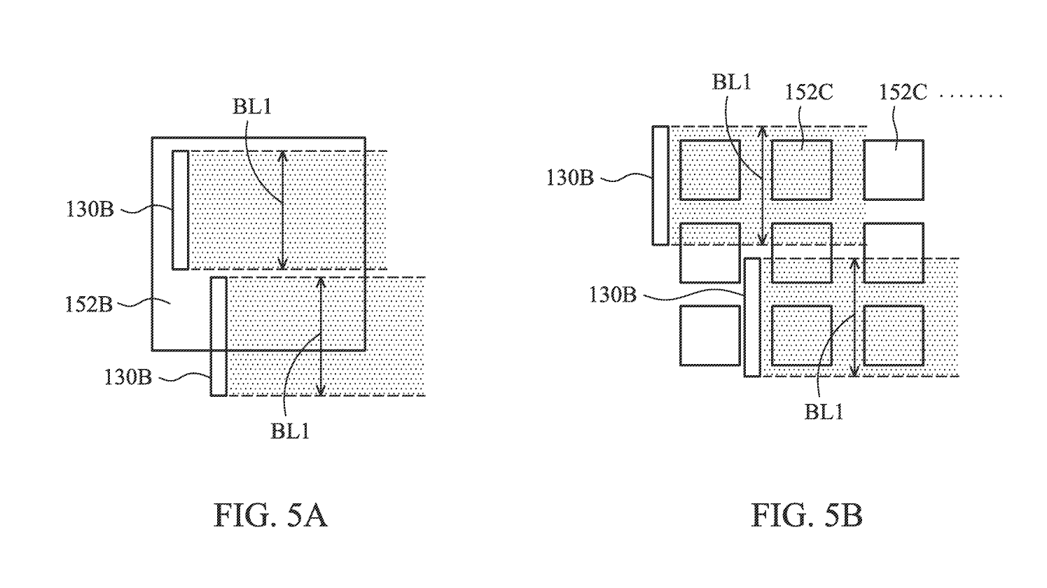

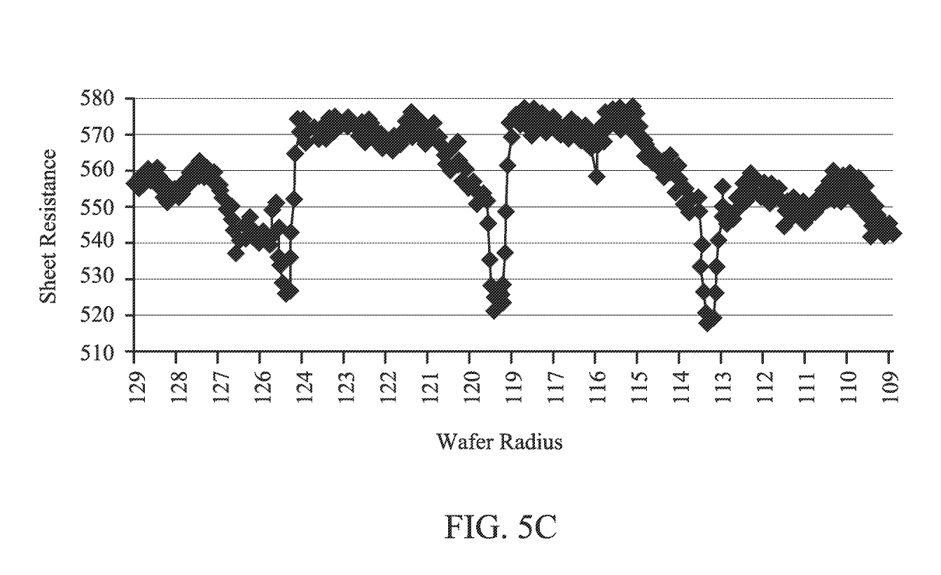

FIGS. 5A and 5B show diagrams of LSA processes without adjustments of the laser beam. Generally, although the die size relative to a silicon wafer may vary in response to different applications, the beam length of a laser beam for LSA is usually constant. That is, if there is no computing device for adjusting the beam length, the laser beam may be much wider or narrower than the die size relative to the silicon wafer. As shown in FIG. 5A, when a laser beam 130B is projected onto a silicon wafer, the beam length BL1 of the laser beam 130B is smaller than the die size of each die 152B. It is understood that the beam length may be defined as the spacing between two opposite edges of the laser beam projected on the silicon wafer, and the die size may be defined as a length or a width of each die of the silicon wafer. Alternatively, as shown in FIG. 5B, when the laser beam 130B is projected onto another silicon wafer, the beam length BL1 of the laser beam 130B is larger than the die size of each die 152C. During the LSA process, the projected position of the laser beam is moved along scanning paths on a silicon wafer one after another. However, when two adjacent scanning paths are too close to each other, regions on the silicon wafer are annealed by the laser beam two or more times. Those regions, which are considered laser-overlapping regions, may include many dies, and the dies may have non-uniform characteristic distribution as a result. For example, FIG. 5C shows a diagram of sheet resistances on the silicon wafer without adjustments of the laser beam. According to the measurement of FIG. 5C, after some laser-overlapping regions on the silicon wafer are annealed two or more times, the dies arranged within the laser-overlapping regions have lower sheet resistances than the other dies do. Accordingly, the annealed dies on the silicon wafer will not have uniform characteristic distribution, and the stitch effect leads to a lower wafer yield. It is understood that other than sheet resistances, the non-uniform characteristic distribution may further affect leakages, saturation currents, and/or voltages of the silicon wafer.

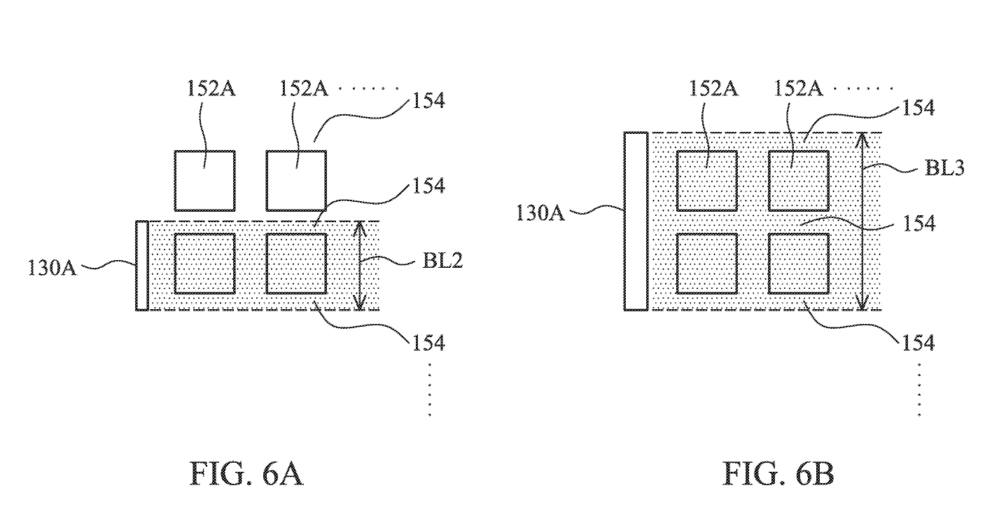

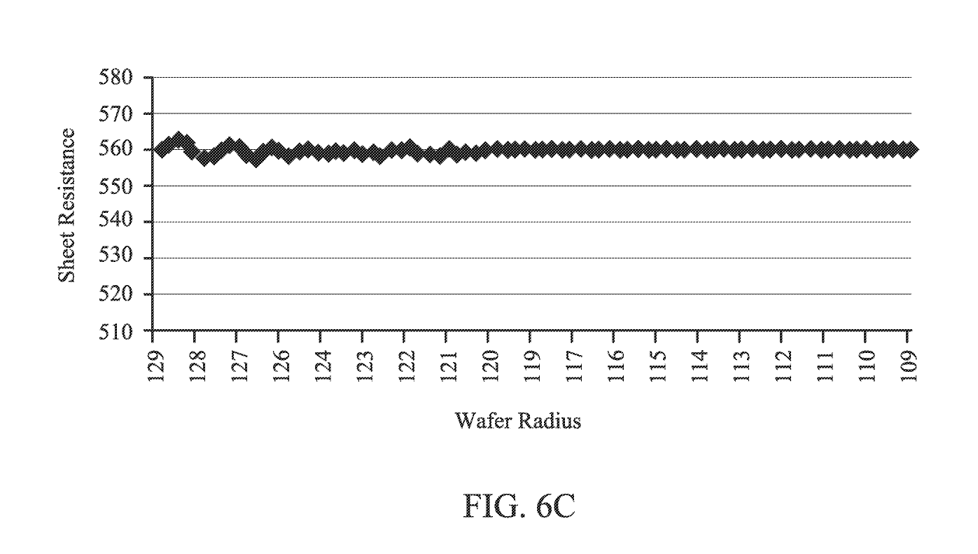

FIGS. 6A and 6B show diagrams of LSA processes in accordance with some embodiments of the disclosure. For both the embodiments of FIGS. 6A and 6B, the laser generator 120 and/or the movable stage 140 may be controlled by the computing device 110 according to the analyzed input mask information DIN. In the embodiment of FIG. 6A, the beam length BL2 of the laser beam 130A is adjusted to be substantially equal to the die size relative to the silicon wafer 150. In the embodiment of FIG. 6B, the beam length BL3 of the laser beam 130A is adjusted to be substantially equal to a multiple (e.g., 2, 3, or 4) of the die size relative to the silicon wafer 150. In some embodiments, the beam length BL2 or BL3 is defined as the spacing between two opposite edges of the laser beam 130A projected on the silicon wafer 150, and the die size is defined as a length or a width of each die 152A of the silicon wafer 150. In some embodiments, when the laser beam 130A is projected onto the silicon wafer 150 for LSA, two opposite edges of the projected laser beam 130A may be further arranged to be aligned with any two scrub-lines 154 on the silicon wafer 150, respectively. In some embodiments, each edge of the projected laser beam 130A is aligned with a centerline of a respective scrub-line 154, but it is not limited thereto. In some embodiments, the projected laser beam is configured to overlap with at least one die and each edge of the projected laser beam is configured to overlap with the spacing between adjacent dies.

In some embodiments discussed above, the spacing between any two adjacent dies 152A (i.e., the width of the scrub-line 154 therebetween) is much smaller than the die size and is negligible. In some embodiments, when the spacing between the dies 152A is considered, and the beam length of the laser beam 130A is adjusted as follows. In some embodiments, the beam length of the laser beam 130A is at least equal to the die size, but shorter than the die size plus 2 times the spacing between two adjacent dies 152A. In some embodiments, the beam length of the laser beam 130A is at least equal to the die size, but shorter than the die size plus 1 time the spacing between two adjacent dies 152A. In some embodiments, the beam length of the laser beam 130A is at least equal to the die size, but shorter than the die size plus 0.5 times the spacing between two adjacent dies 152A. In some embodiments, when the laser beam 130A passes over N rows of dies 152A, the beam length of the laser beam 130A is at least equal to N times the die size plus (N−1) times the spacing between two adjacent dies 152A, but shorter than N times the die size plus (N+1) times the spacing between two adjacent dies 152A. In some embodiments, multiple laser beams 130A are used. In some embodiments, only one or only two laser beams 130A are used. In some embodiments, the laser beams 130A are movable while the silicon wafer 150 remains stationary. In some embodiments, the laser beams 130A move in the same or different direction. In some embodiments, at least two of the scanned portions or areas at least overlap in a space between the successive rows or columns of dies 152A that are scanned. In some embodiments, the scanned portions or areas do not overlap in the space between the successive rows or columns of dies 152A that are scanned.

The aforementioned alignment may be achieved by moving either the movable stage 140 or the laser beam 130A of the laser generator 120. In some embodiments, the control signal SC further indicates a start position of the movable stage 140, and/or a stepping size of the laser beam 130A or the movable stage 140, so as to control the relative positions of the movable stage 140 and the laser beam 130A precisely. In such a design, during the LSA process, even if some laser-overlapping regions on the silicon wafer 150 are annealed by the laser beam 130A two or more times due to process variations, the laser-overlapping regions may all substantially fall within the scrub-lines 154 (or in the spacing between the dies), rather than within the dies 152A. Therefore, the dies 152A are not negatively affected by the overlapping laser beam, and they can have a more uniform characteristic distribution. Mechanisms of the embodiments can eliminate the stitch effect on the silicon wafer 150 and further increase the wafer yield. For example, FIG. 6C shows a diagram of sheet resistances on the silicon wafer 150 in accordance with some embodiments of the disclosure. According to the measurement result of FIG. 6C, the sheet resistances appear to have a relatively uniform distribution over different radii of the silicon wafer 150 after the appropriate adjustments of the laser generator 120 and/or the movable stage 140 are made based on the analyzed input mask information DIN. In alternative embodiments, the input mask information DIN is generated by using an optical device to measure the characteristics of the silicon wafer 150, and detailed information about the silicon wafer 150 is obtained accordingly.

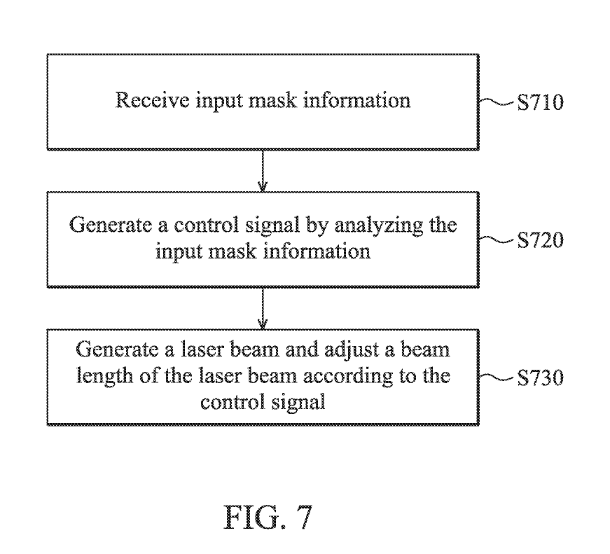

FIG. 7 shows a flowchart of a method for LSA in accordance with some embodiments of the disclosure. In operation S710, input mask information is received via a computing device. In some embodiments, the input mask information includes a die size, a center die position, and/or a scrub-line dimension relative to a silicon wafer. For example, the die size may be used to adjust a beam length of a laser beam, and the center die position and the scrub-line dimension may be used to adjust a relative position of a silicon wafer to be annealed. In operation S720, a control signal is generated via the computing device by analyzing the input mask information. In operation S730, a laser beam is generated, and the beam length of the laser beam is adjusted according to the control signal. The beam length of the laser beam may be substantially equal to the die size or a multiple of the die size. The laser beam may be generated via a laser generator which includes a laser source, mirrors, and prisms. The laser generator may be coupled to the computing device and controlled by the computing device. In some embodiments of the method, a silicon wafer is positioned onto a movable stage, and the movable stage is moved via a stage controller according to the control signal. In some embodiments, the laser beam is projected onto the silicon wafer for LSA. The stage controller may be coupled to the computing device and controlled by the computing device. The control signal may indicate mirror and prism parameters, a start position of the movable stage, and/or a stepping size of the laser beam or the movable stage. The silicon wafer includes multiple dies and multiple scrub-lines therebetween in accordance with some embodiments of the disclosure. When the laser beam is projected onto the silicon wafer for LSA, two edges of the laser beam may be arranged to be aligned with two scrub-lines on the silicon wafer, respectively. It is noted that any one or more features of the embodiments of FIGS. 1-6 may be applied to the method for LSA as shown in FIG. 7.

Mechanisms of adjustable laser beams for LSA (Laser Spike Annealing) are provided. A computing device receives input mask information relative to a silicon wafer, and analyzes the input mask information so as to generate a control signal. A laser generator generates and adjusts a laser beam according to the control signal. The input mask information may include many features of the silicon wafer which is going to be annealed. When the generated laser beam is projected onto the silicon wafer for LSA, the beam length and/or the projected position of the generated laser beam may be automatically adjusted in response to the analyzed input mask information via the computing device and the laser generator, and the adjusted laser beam may be consistent with the die size and/or the scrub-line arrangement of the silicon wafer to improve the total performance thereof. As a result, the disclosed mechanisms of adjustable laser beams for LSA can effectively reduce the probability for the die regions on the silicon wafer to be annealed more times, thereby eliminating the stitch effect on the silicon wafer and further increasing the wafer yield.

In some embodiments, an apparatus for LSA (Laser Spike Annealing) is provided. The apparatus includes a computing device and a laser generator. The computing device receives input mask information, and analyzes the input mask information so as to generate a control signal. The laser generator generates a laser beam, and adjusts a beam length of the laser beam according to the control signal.

In some embodiments, an apparatus for LSA (Laser Spike Annealing) on a silicon wafer is provided. The apparatus includes a computing device, a laser generator, a movable stage, and a stage controller. The computing device receives input mask information, and analyzes the input mask information so as to generate a control signal. The laser generator generates and adjusts a laser beam according to the control signal. The silicon wafer is positioned on the movable stage. The stage controller moves the movable stage according to the control signal.

In some embodiments, a method for LSA (Laser Spike Annealing) is provided. The method includes the steps of receiving input mask information, generating a control signal by analyzing the input mask information, and generating a laser beam and adjusting a beam length of the laser beam according to the control signal.

The method of the disclosure, or certain aspects or portions thereof, may take the form of a program code (i.e., executable instructions) embodied in tangible media, such as floppy diskettes, CD-ROMS, hard drives, or any other machine-readable storage medium, wherein, when the program code is loaded into and executed by a machine, such as a computer, the machine thereby becomes an apparatus for practicing the methods. The methods may also be embodied in the form of a program code transmitted over some transmission medium, such as electrical wiring or cabling, through fiber optics, or via any other form of transmission, wherein, when the program code is received and loaded into and executed by a machine, such as a computer, the machine becomes an apparatus for practicing the disclosed methods. When implemented on a general-purpose processor, the program code combines with the processor to provide a unique apparatus that operates analogously to application specific logic circuits.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for ordinal term) to distinguish the claim elements.

Although embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An apparatus for laser spike annealing (LSA), comprising:
a computing device, receiving input mask information, and analyzing the input mask information so as to generate a control signal; and
a laser generator, generating a laser beam, and adjusting a beam length of the laser beam according to the control signal.

2. The apparatus as claimed in claim 1, wherein the input mask information comprises a die size, a center die position, and/or a scrub-line dimension relative to a silicon wafer.

3. The apparatus as claimed in claim 2, wherein the beam length is substantially equal to the die size or a multiple of the die size.

4. The apparatus as claimed in claim 1, wherein the laser generator comprises a laser source and a plurality of mirrors and prisms.

5. The apparatus as claimed in claim 4, wherein the control signal indicates mirror and prism parameters.

6. The apparatus as claimed in claim 5, wherein the mirror and prism parameters comprise focal points, mirror and prism rotation angles, mirror and prism positions, and/or laser beam distortion relative to the mirrors and prisms.

7. An apparatus for laser spike annealing (LSA) on a silicon wafer, comprising:
a computing device, receiving input mask information, and analyzing the input mask information so as to generate a control signal;
a laser generator, generating and adjusting a laser beam according to the control signal;
a movable stage, wherein the silicon wafer is positioned on the movable stage; and
a stage controller, moving the movable stage according to the control signal.

8. The apparatus as claimed in claim 7, wherein the input mask information comprises a die size, a center die position, and/or a scrub-line dimension relative to the silicon wafer.

9. The apparatus as claimed in claim 8, wherein a beam length of the laser beam is substantially equal to the die size or a multiple of the die size.

10. The apparatus as claimed in claim 7, wherein the laser generator comprises a laser source and a plurality of mirrors and prisms.

11. The apparatus as claimed in claim 10, wherein the control signal indicates mirror and prism parameters, a start position of the movable stage, and a stepping size of the laser beam or the movable stage.

12. The apparatus as claimed in claim 11, wherein the mirror and prism parameters comprise focal points, mirror and prism rotation angles, mirror and prism positions, and/or laser beam distortion relative to the mirrors and prisms.

13. The apparatus as claimed in claim 11, wherein the silicon wafer comprises a plurality of scrub-lines, and when the laser beam is projected onto the silicon wafer for LSA, edges of the projected laser beam are arranged to be aligned with some of the scrub-lines.

14. A method for laser spike annealing (LSA), comprising the steps of:
receiving input mask information;
generating a control signal by analyzing the input mask information; and
generating a laser beam and adjusting a beam length of the laser beam according to the control signal.

15. The method as claimed in claim 14, wherein the input mask information comprises a die size, a center die position, and/or a scrub-line dimension relative to a silicon wafer.

16. The method as claimed in claim 15, wherein the beam length is substantially equal to the die size or a multiple of the die size.

17. The method as claimed in claim 14, wherein the laser beam is generated by a laser generator which comprises a laser source and a plurality of mirrors and prisms.

18. The method as claimed in claim 17, further comprising:
positioning a silicon wafer onto a movable stage;
moving the movable stage according to the control signal; and
projecting the laser beam onto the silicon wafer for LSA.

19. The method as claimed in claim 18, wherein the control signal indicates mirror and prism parameters, a start position of the movable stage, and a stepping size of the laser beam or the movable stage.

20. The method as claimed in claim 18, wherein the silicon wafer comprises a plurality of scrub-lines, and when the laser beam is projected onto the silicon wafer for LSA, edges of the projected laser beam are arranged to be aligned with some of the scrub-lines.
